(19) United States
(12) Patent Application Publication
(10) Pub. No.: US 2026/0314471 A1
(43) Pub. Date: Oct. 8, 2026

(54) SEMICONDUCTOR PACKAGE INCLUDING CONNECTION BUMP

(71) Applicant: Samsung Electronics Co., Ltd., Suwon-si (KR)

(72) Inventors: Junho Lee, Suwon-si (KR); Insik Han, Suwon-si (KR)

(73) Assignee: Samsung Electronics Co., Ltd., Suwon-si (KR)

(21) Appl. No.: 19/343,503

(22) Filed: Sep. 29, 2025

(30) Foreign Application Priority Data
Apr. 4, 2025 (KR) 10-2025-0044085

(51) Int. Cl. H01L 23/00; H01L 23/31; H01L 23/498; H01L 23/538

(52) U.S. Cl. CPC H10W 74/117; H10W 70/65; H10W 70/611; H10W 70/635; H10W 72/07236; H10W 72/07253; H10W 72/07254; H10W 72/237; H10W 72/248; H10W 90/701; H10W 90/724

(57) ABSTRACT

A semiconductor package according to example embodiments of the present disclosure includes: a package substrate; a semiconductor chip including a first surface; and a plurality of connection bumps disposed below the first surface of the semiconductor chip, and the plurality of connection bumps include a first group of connection bumps and a second group of connection bumps, each of the first group of the connection bumps include a first connection pillar and a first connection solder, each of the second group of the connection bumps include a second connection pillar and a second connection solder, in a vertical direction, and in at least one of the second group of connection bumps, an upper end of the second connection solder disposed on a level lower than a level of an upper end of the first connection solder of each of the first group of the connection bumps.

### CROSS-REFERENCE TO RELATED APPLICATIONS

This present application claims priority to and the benefit under 35 U.S.C. § 119(a)-(d) of Korean Patent Application No. 10-2025-0044085 filed on Apr. 4, 2025, in the Korean Intellectual Property Office, the entire disclosure of which is incorporated herein by reference.

### FIELD

The present disclosure relates to a semiconductor package and a manufacturing method of the same.

### BACKGROUND

According to the development of the electronics industry develops and user demands, electronic devices have become smaller and lighter, and semiconductor packages used in electronic devices are required to be smaller and lighter, as well as high-performance and high-capacity. In order to achieve small size and lightweightedness, as well as high-performance and high-capacity, research and development on the structure in which semiconductor chips and package substrates on which semiconductor chips are mounted has been continuously being conducted.

### SUMMARY

Aspects of the present disclosure provide an improved semiconductor package having improved reliability.

Aspects of the present disclosure provide a manufacturing method of a semiconductor package having improved reliability.

A semiconductor package according to example embodiments may include: a package substrate including a plurality of upper connection pads; a semiconductor chip disposed on the package substrate and including a first surface facing the package substrate, the first surface including a first region and a second region; and a plurality of connection bumps disposed below the first surface of the semiconductor chip and electrically connected to the plurality of upper connection pads, and the plurality of connection bumps may include a first group of connection bumps disposed within the first region of the first surface and a second group of connection bumps disposed within the second region of the first surface, each of the first group of the connection bumps may include a first connection pillar and a first connection solder electrically connecting the first connection pillar to one of the plurality of upper connection pads, each of the second group of the connection bumps may include a second connection pillar and a second connection solder electrically connecting the second connection pillar to one of the plurality of upper connection pads, in a vertical direction, substantially perpendicular to the first surface, at least a portion of the second region may have a greater separation distance from an upper surface of the package substrate than the first region, and in at least one of the second group of connection bumps, an upper end of the second connection solder may be disposed on a level lower than a level of an upper end of the first connection solder of each of the first group of the connection bumps.

A semiconductor package according to example embodiments may include: a package substrate including a first upper connection pad and a second upper connection pad; a semiconductor chip disposed on the package substrate and electrically connected to the first upper connection pad and the second upper connection pad; and connection bumps including a first connection bump connected to the first upper connection pad and a second connection bump connected to the second upper connection pad, which are disposed between the package substrate and the semiconductor chip, and the first connection bump may include: a first connection pillar on a lower surface of the semiconductor chip; and a first connection solder covering a lower surface and a side surface of the first connection pillar and an upper surface of the first upper connection pad, and the second connection bump may include: a second connection pillar on the lower surface of the semiconductor chip; and a second connection solder covering a lower surface of the second connection pillar and an upper surface of the second upper connection pad, and a first gap between the lower surface of the first connection pillar and the upper surface of the first upper connection pad may be less than a second gap between the lower surface of the second connection pillar and the upper surface of the second upper connection pad.

A semiconductor package according to example embodiments may include: a package substrate body; upper connection pads on an upper surface of the package substrate body; a semiconductor chip on an upper surface of the package substrate body; connection pillars on a lower surface of the semiconductor chip; and connection solders disposed between the connection pillars and the upper connection pads and electrically connecting the upper connection pads and the connection pillars, and the connection solders may include: a first connection solder in contact with a first upper connection pad, among the upper connection pads, and a first connection pillar, among the connection pillars; and a second connection solder in contact with a second upper connection pad, among the upper connection pads, and a second connection pillar, among the connection pillars, and the first connection solder may surround at least a portion of a side surface of the first connection pillar, and an area in which the first connection solder is in contact with the first connection pillar and the first upper connection pad is greater than an area in which the second connection solder is in contact with the second connection pillar and the second connection solder.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1A is a schematic cross-sectional view illustrating a semiconductor package according to example embodiments;

FIG. 1B is a schematic plan view illustrating a semiconductor package according to example embodiments;

FIG. 1C is a schematic partially enlarged cross-sectional view illustrating a semiconductor package according to example embodiments;

FIG. 1D is a schematic partially enlarged cross-sectional view illustrating a semiconductor package according to example embodiments;

FIG. 2A is a schematic partially enlarged cross-sectional view illustrating a semiconductor package according to example embodiments;

FIG. 2B is a schematic partially enlarged cross-sectional view illustrating a semiconductor package according to example embodiments;

FIG. 3 is a schematic partially enlarged cross-sectional view illustrating a semiconductor package according to example embodiments;

FIG. 4A is a schematic cross-sectional view illustrating a semiconductor package according to example embodiments;

FIG. 4B is a schematic plan view illustrating a semiconductor package according to example embodiments;

FIG. 5 is a schematic plan view illustrating a semiconductor package according to example embodiments;

FIG. 6 is a schematic plan view illustrating a semiconductor package according to example embodiments;

FIG. 7 is a schematic plan view illustrating a semiconductor package according to example embodiments;

FIG. 8A is a schematic cross-sectional view illustrating a semiconductor package according to example embodiments;

FIG. 8B is a schematic cross-sectional view illustrating a semiconductor package according to example embodiments;

FIGS. 9A, 10A, 11A and 12A are cross-sectional views illustrating a process sequence for explaining a manufacturing method of a semiconductor package according to example embodiments;

FIGS. 9B, 10B, 11B and 12B are plan views illustrating a process sequence for explaining a manufacturing method of a semiconductor package according to example embodiments;

FIGS. 10C, 11C and 12C are partially enlarged cross-sectional views illustrating a process sequence for explaining a manufacturing method of a semiconductor package according to example embodiments;

FIGS. 10D, 11D and 12D are partially enlarged plan views illustrating a process sequence for explaining the manufacturing method of a semiconductor package according to example embodiments;

FIGS. 13, 14A, 15A and 16 are cross-sectional views illustrating a process sequence for explaining the manufacturing method of a semiconductor package according to example embodiments; and

FIGS. 14B and 15B are partially enlarged cross-sectional views illustrating the process sequence for explaining the manufacturing method of a semiconductor package according to example embodiments.

### DETAILED DESCRIPTION

Hereinafter, example embodiments of the present disclosure will be described with reference to the accompanying drawings.

Hereinafter, example embodiments of the present disclosure will be described with reference to the accompanying drawings. Hereinafter, it may be understood that the expressions such as “on,” “above,” “upper,” “below”, “beneath,” “lower,” and “side” merely indicated based on drawings unless otherwise stated.

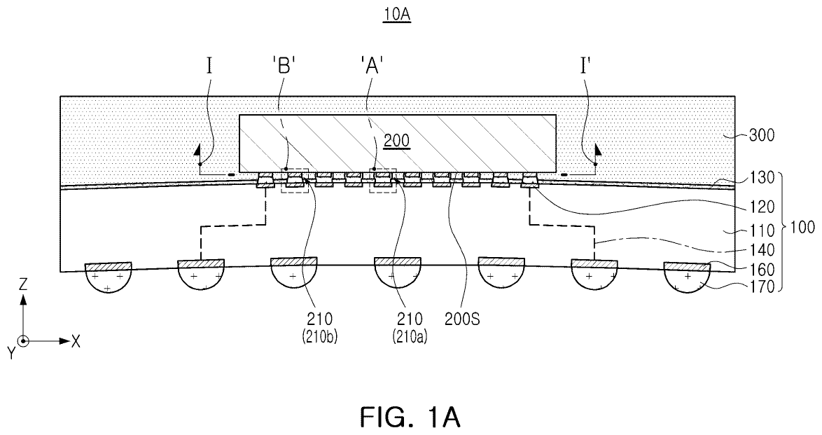

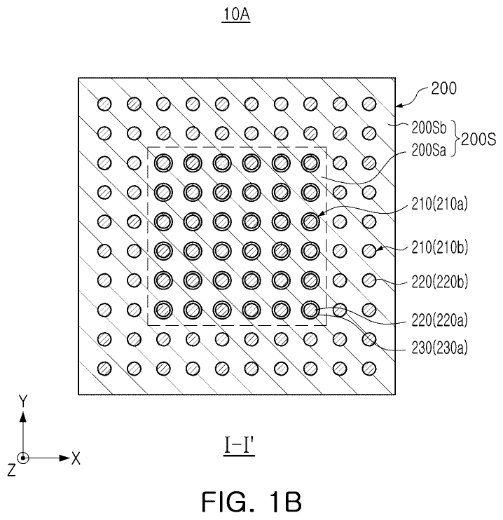

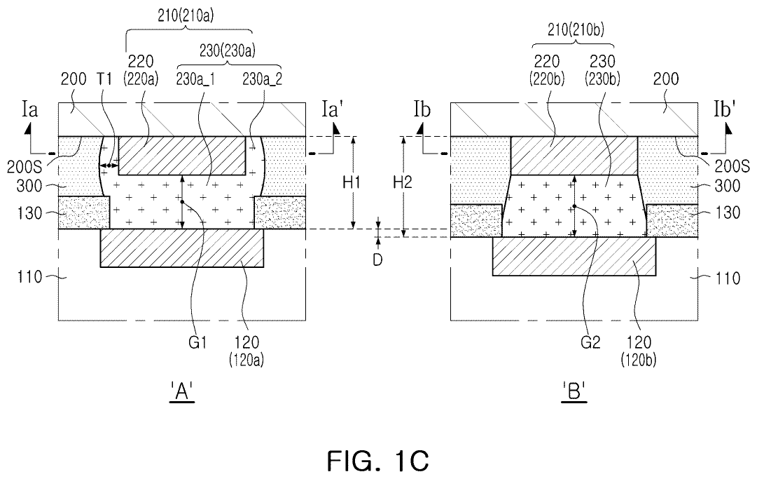

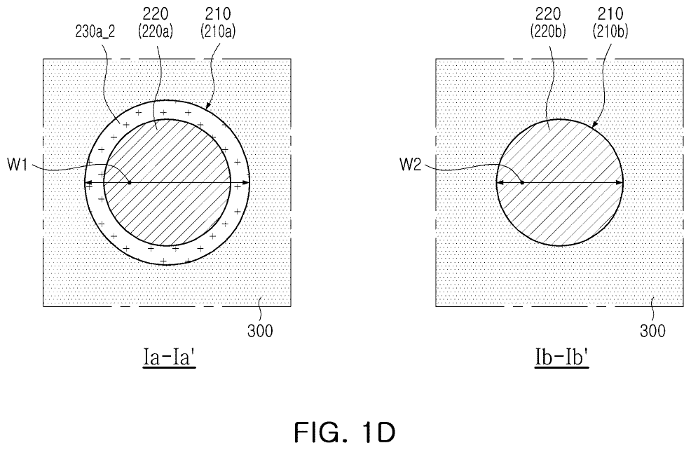

FIG. 1A is a schematic cross-sectional view illustrating a semiconductor package according to example embodiments.

FIG. 1B is a schematic plan view illustrating a semiconductor package according to example embodiments. FIG. 1B schematically illustrates a cross-section taken along the cutting line I-I′ of FIG. 1A. FIG. 1B schematically illustrates a shape of a first surface 200S of a semiconductor chip 200.

FIG. 1C is a schematic partially enlarged cross-sectional view illustrating a semiconductor package according to example embodiments. FIG. 1C is an enlarged view illustrating region ‘A’ and region ‘B’ of FIG. 1A. The region A′ illustrates example embodiments of a first group of connection bumps 210a, and the region ‘B’ illustrates example embodiments of a second group of connection bumps 210b.

FIG. 1D is a schematic partial enlarged plan view illustrating a semiconductor package according to example embodiments. FIG. 1D schematically illustrates cross-sections taken along the cutting line Ia-Ia′ of region ‘A’ and the cutting line Ib-Ib′ of region ‘B’ of FIG. 1C.

Referring to FIGS. 1A to 1D, a semiconductor package 10A may include a package substrate 100, a semiconductor chip 200, a plurality of connection bumps 210, and an encapsulant 300.

A warpage in which a substrate is bent may be formed in a package substrate body 110 on which the semiconductor chip 200 is mounted. By the warpage of the package substrate body 110, a plurality of upper connection pads 120 may include first upper connection pads 120a disposed close to the first surface 200S of the semiconductor chip 200 and second upper connection pads 120b disposed relatively distant from the first surface 200S of the semiconductor chip 200. The first upper connection pads 120a may be in contact with and connected to a first group of connection bumps 210a, and the second upper connection pads 120b may be in contact with and connected to a second group of connection bumps 210b. First connection solders 230a of the first group of connection bumps 210a may include a peripheral portion 230a_2 surrounding a side surface of first connection pillars 220a. By the structure of these first connection bumps 210a, the first surface 200S of the semiconductor chip 200 may be induced to be sufficiently close to an upper surface of the package substrate body 110 during a process of mounting the semiconductor chip 200 on the package substrate 100. Accordingly, the second upper connection pads 120b that are relatively distant from the first surface 200S of the semiconductor chip 200 may be stably connected to the second group of connection bumps 210b, and a semiconductor package with improved reliability may be provided. Details related thereto will be described in detail below in the description of each configuration.

The package substrate 100 is a support substrate on which the semiconductor chip 200 is mounted, and may be a semiconductor package substrate including a printed circuit board (PCB), a ceramic substrate, a glass substrate, a tape interconnection substrate, and the like. The package substrate 100 may include a package substrate body 110, upper connection pads 120, an upper protective layer 130, an interconnection circuit 140, lower connection pads 160, and external connection conductors 170.

The package substrate body 110 may have an upper surface facing the first surface 200S of the semiconductor chip 200 and a lower surface opposing the upper surface. The upper surface and the lower surface of the package substrate body 110 may be referred to as an upper surface and lower surface of the package substrate 100. The description of the package substrate body 110 may include a description of the package substrate 100 itself. The package substrate body 110 may include different materials depending on the type. For example, when the package substrate 100 is a printed circuit board, the package substrate 100 may be in the form in which an interconnection layer is additionally stacked on one surface or both surfaces of a body copper foil laminate or a copper foil laminate. The package substrate body 110 may have warpage according to example embodiments. In example embodiments, as illustrated in FIG. 1A, the package substrate body 110 may have an edge partially bent downwardly. The shape, degree, and the like, of the warpage of the package substrate body 110 may be variously modified according to example embodiments, and the description referring to FIGS. 1A to 1D describes example embodiments in which an edge of the package substrate body 110 is bent downwardly. Depending on the warpage occurring in the package substrate body 110, a gap between the upper surface of the package substrate body 110 and the first surface 200S of the semiconductor chip 200 may not be constant. In a vertical direction, perpendicular to the first surface 200S of the semiconductor chip 200, a separation distance between a first region 200Sa disposed in the center of the first surface 200S of the semiconductor chip 200 and the upper surface of the package substrate body 110 may be less than a separation distance between a second region 200Sb disposed at an edge of the first surface 200S and the upper surface of the package substrate body 110. In the vertical direction, the edge of the first surface 200S may include a portion having a greater separation distance from the upper surface of the package substrate 100 than the first region 200Sa. In the vertical direction, a first separation distance H1 between a portion of the first region 200Sa and the upper surface of the package substrate body 110 may be less than a second separation distance H2 between a portion of the second region 200Sb and the upper surface of the package substrate body 110. The package substrate body 110 may include an insulating material that electrically and physically protects the interconnection circuit 140, and may include, for example, a thermosetting resin such as an epoxy resin, a thermoplastic resin such as a polyimide, or a prepreg including an inorganic filler or/and glass fiber (Glass Fiber, Glass Cloth or Glass Fabric), Ajinomoto Build-up Film (ABF), and Frame Retardant 4 (FR4).

The upper connection pads 120 may be disposed on the upper surface of the package substrate body 110. The upper connection pads 120 may be disposed in plural. Each of the plurality of upper connection pads 120 may be in contact with and electrically connected to each of the plurality of connection bumps 210. The plurality of upper connection pads 120 may be electrically connected to the semiconductor chip 200 through the plurality of connection bumps 210. Each of the plurality of upper connection pads 120 may be in contact with a connection solder 230 of the connection bump 210. An upper surface of the upper connection pad 120 may be in contact with the connection solder 230. In example embodiments, an edge of the upper surface of the upper connection pad 120 may be in contact with the upper protective layer 130, and at least a portion of the upper surface of the upper connection pad 120 exposed from the upper protective layer 130 may be in contact with the connection solder 230. The plurality of upper connection pads 120 may be electrically connected to the plurality of lower connection pads 160 through the interconnection circuit 140.

The plurality of upper connection pads 120 may include first upper connection pads 120a in contact with and connected to the first group of connection bumps 210a and second upper connection pads 120b in contact with and connected to the second group of connection bumps 210b. Upper surfaces of the first upper connection pads 120a and upper surfaces of the second upper connection pads 120b may be disposed on different levels by the warpage of the package substrate body 110. An upper surface of at least portions of the first upper connection pads 120a connected to the first group of connection bumps 210a may be disposed closer to the first surface 200S than the upper surfaces of each of the second upper connection pads 120b connected to the second group of connection bumps 210b. Referring to FIG. 1C, a pad level difference D may be present between the upper surface of the first upper connection pad 120a and the upper surface of the second connection bump 210b, which is one of the second connection bumps 210b. In this specification, a level of a configuration may be defined as being determined by a position in a vertical direction (e.g., Z-direction) of the first surface 200S based on the first surface 200S. The upper surface of the first upper connection pad 120a may be disposed closer to the first surface 200S of the semiconductor chip 200 by the pad level difference D than the upper surface of the second upper connection pad 120b. That is, the upper surface of the first upper connection pad 120a may be disposed on a level higher than the upper surface of the second upper connection pad 120b by the pad level difference D. An average separation distance between the upper surface of the first upper connection pads 120a and the first surface 200S may be less than an average separation distance between the upper surface of the second upper connection pads 120b and the first surface 200S. An average level of the upper surface of the first upper connection pads 120a may be disposed on a level higher than an average level of the upper surface of the second upper connection pads 120b. The first upper connection pads 120a and the second upper connection pads 120b may have the same or similar features except for the contents described to distinguish features from each other.

The plurality of upper connection pads 120 may include more or fewer than those illustrated in FIGS. 1A and 1B. Although not specifically illustrated, the upper connection pads 120 may further include dummy upper connection pads not electrically connected to the semiconductor chip 200 or the interconnection circuit 140. The upper connection pads 120 may include, for example, at least one metal material of aluminum (Al), copper (Cu), nickel (Ni), tungsten (W), platinum (Pt), or gold (Au), but the present disclosure is not limited thereto.

The upper protective layer 130 may cover at least a portion of the upper surface of the package substrate body 110, i.e., the upper surface of the package substrate 100. In example embodiments, the upper protective layer 130 may cover a portion of the upper surface of each of the plurality of upper connection pads 120. In example embodiments, the upper protective layer 130 may cover at least a portion of an edge of the upper surface of each of the plurality of upper connection pads 120. In example embodiments, the upper protective layer 130 may include openings exposing at least a portion of the upper surface of each of the plurality of upper connection pads 120. In example embodiments, the upper protective layer 130 may be in contact with at least one of the plurality of connection bumps 210. In example embodiments, the upper protective layer 130 may be in contact with the connection solders 230 of each of the plurality of connection bumps 210. The upper protective layer 130 may include an insulating material protecting the upper connection pads 120 and the package substrate body 110, and may include, for example, a thermosetting resin such as an epoxy resin, a thermoplastic resin such as a polyimide, or a prepreg including an inorganic filler or/and glass fiber (Glass Fiber, Glass Cloth or Glass Fabric), an Ajinomoto Build-up Film (ABF), and Frame Retardant 4 (FR4). Although not specifically illustrated, the package substrate 100 may further include a lower protective layer below a lower surface of the package substrate body 110, and the lower protective layer may have the characteristics identical to or similar to the upper protective layer 130 except for the position in which the lower protective layer is disposed.

The interconnection circuit 140 may electrically connect a plurality of upper connection pads 120 and a plurality of lower connection pads 160 within the package substrate body 110. Although schematically illustrated in FIG. 1A, the interconnection circuit 140 may include a conductive pattern and a conductive via forming an electrical connection path. The interconnection circuit 140 illustrated in FIG. 1A schematically illustrates the electrical connection path formed by the conductive pattern and the conductive via, and is not intended to limit the plurality of upper connection pads 120 and the plurality of lower connection pads 160 connected to the interconnection circuit 140. The interconnection circuit 140 may include at least one metal of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C), or an alloy formed of two or more metals.

The lower connection pads 160 may be disposed on the lower surface of the package substrate body 110. The lower connection pads 160 may be disposed in plural. Each of the plurality of lower connection pads 160 may be disposed below each of a plurality of external connection conductors 170. Although not specifically illustrated, a lower protection layer having similar characteristics to the upper protection layer 130 may be disposed on the lower surface of the package substrate body 110, and the lower connection pads 160 may be in contact with the lower protection layer. The plurality of lower connection pads 160 may be electrically connected to the plurality of upper connection pads 120 through the interconnection circuit 140. The plurality of lower connection pads 160 may include more or fewer than those illustrated in FIG. 1A. In example embodiments, the lower connection pads 160 may further include dummy lower connection pads not electrically connected to the interconnection circuit 140. The lower connection pads 160 may include, for example, at least one metal material of aluminum (Al), copper (Cu), nickel (Ni), tungsten (W), platinum (Pt), or gold (Au), but the present disclosure is not limited thereto.

The plurality of external connection conductors 170 may be disposed below each of the plurality of lower connection pads 160. The plurality of external connection conductors 170 may be electrically connected to the interconnection circuit 140 through the plurality of lower connection pads 160. The semiconductor package 10A may be connected to an external device through the plurality of external connection conductors 170. The plurality of external connection conductors 170 may include, for example, solder balls. The solder balls may include tin (Sn), bismuth (Bi), lead (Pb), silver (Ag), or alloys thereof.

The semiconductor chip 200 may be mounted on the package substrate 100 in a flip-chip bonding manner. The semiconductor chip 200 may be electrically connected to the upper connection pads 120 of the package substrate 100 through a plurality of connection bumps 210. The semiconductor chip 200 may include a first surface 200S facing the package substrate 100. In this specification, the horizontal direction may be defined as a direction, parallel to the first surface 200S (e.g., X-direction or Y-direction), and the vertical direction may be defined as a direction, perpendicular to the first surface 200S (e.g., Z-direction). A level of a configuration may be determined according to a position disposed in the vertical direction of the first surface 200S. The plurality of connection bumps 210 may be disposed between the first surface 200S of the semiconductor chip 200 and the upper surface of the package substrate 100. The first surface 200S may include a first region 200Sa in which the first group of connection bumps 210a are disposed, and a second region 200Sb in which the second group of connection bumps 210b are disposed. The first region 200Sa may be defined as a region in which the first group of connection bumps 210a are disposed, and the second region 200Sb may be defined as a region in which the second group of connection bumps 210b are disposed. Due to the warpage of the package substrate body 110, in the vertical direction, a separation distance between the upper surface of the package substrate 100 and the second region 200Sb may be greater than a separation distance between the upper surface of the package substrate 100 and the first region 200Sa. In the vertical direction, at least a portion of the second region 200Sb may have a greater separation distance from the upper surface of the package substrate 100 than the first region 200Sa. In the vertical direction, an average separation distance between the second region 200Sb and the upper surface of the package substrate 100 may be greater than an average separation distance between the second region 200Sb and the upper surface of the package substrate 100. A first region 220Sa and a second region 220Sb defined within the first surface 220S may be defined differently according to example embodiments according to the warpage of the package substrate body 110. In example embodiments, when the package substrate body 110 is provided so that a warpage is formed to bend an edge thereof more downwardly than a central portion thereof, similarly to the semiconductor package 10A of FIGS. 1A to 1B, the first region 220Sa may be disposed in a central portion of the first surface 220S, and the second region 220Sb may be disposed in an edge of the first surface 220S. In this case, the second region 220Sb may surround the first region 220Sa.

In example embodiments, the semiconductor chip 200 may be a logic chip including logic circuits such as a central processor (CPU), a graphics processor (GPU), a field programmable gate array (FPGA), an application processor (AP), a digital signal processor, an encryption processor, a microprocessor, a microcontroller, an analog-to-digital converter, and an application-specific IC (ASIC). In example embodiments, the semiconductor chip 200 may be a memory chip including memory circuits such as volatile memory, such as a dynamic RAM (DRAM), a static RAM (SRAM), and nonvolatile memory, such as a phase change RAM (PRAM), a magnetic RAM (MRAM), a resistive RAM (RRAM), and a flash memory. In example embodiments, the semiconductor chip 200 may include a plurality of semiconductor chips vertically stacked, and these plurality of semiconductor chips may be logic chips or memory chips.

The connection bumps 210 may be disposed below the first surface 200S of the semiconductor chip 200. The connection bumps 210 may be disposed between the first surface 200S of the semiconductor chip 200 and the upper connection pads 120 of the package substrate 100, and may be in contact with upper surfaces of the upper connection pads 120. The connection bumps 210 may electrically connect the semiconductor chip 200 and the upper connection pads 120 of the package substrate 100. The connection bumps 210 may be disposed in plural. The plurality of connection bumps 210 may include more or less than the number illustrated. The plurality of connection bumps 210 may include a first group of connection bumps 210a disposed in the first region 220Sa and a second group of connection bumps 210b disposed in the second region 220Sb. In example embodiments, the second group of connection bumps 210b may be disposed in a form surrounding the first group of connection bumps 210a. In example embodiments, the second group of connection bumps 210b may be disposed closer to the edge of the first surface 200S than the first group of connection bumps 210a. In example embodiments, the first group of connection bumps 210a may be disposed at a ratio of 30% to 70% of the plurality of connection bumps 210, and the remainder may be the second group of connection bumps 210b. In example embodiments, the first group of connection bumps 210a may be disposed at a ratio of 20% to 80% or 10% to 90%. A ratio of the first group of connection bumps 210a, among the plurality of connection bumps 210, may vary according to example embodiments. If the ratio of the first group of connection bumps 210a, among the plurality of connection bumps 210, is less than the ratio described above, an effect of inducing the first surface 200S of the semiconductor chip 200 to be disposed close to the upper surface of the package substrate body 110 may not occur or may occur insufficiently. Even if the ratio of the first group of connection bumps 210, among the plurality of connection bumps 210, is greater than the ratio described above, similarly, the effect of inducing the first surface 200S of the semiconductor chip 200 to be disposed close to the upper surface of the package substrate body 110 may be reduced. Details related thereto will be described in detail below in the description of a manufacturing method.

Each of the plurality of connection bumps 210 may include a connection pillar 220 and a connection solder 230. The first connection bump 210a, which is one of the first group of connection bumps 210a, may include a first connection pillar 220a and a first connection solder 230a. The first group of connection bumps 210a may have the characteristics of a first connection bump 210a described below. The second connection bump 210b, which is one of the second group of connection bumps 210b, may include a second connection pillar 220b and a second connection solder 230b. The connection bumps 210b of the second group may have the characteristics of a second connection bump 210b described below. The first group of connection bumps 210a and the second group of connection bumps 210b may have different characteristics distinguished by the first connection solder 230a and the second connection solder 230b respectively included therein. A volume of each of the first connection bumps 210a of the first group may be greater than a volume of each of the connection bumps 210b of the second group. A maximum planar area of each of the connection bumps 210a of the first group may be greater than a maximum planar area of each of the connection bumps 210b of the second group. The first group of connection bumps 210a may be in contact with the first surface 200S. At least one of the second group of connection bumps 210b may be spaced apart from the first surface 200S and may not be in contact with the first surface 200S. Referring to FIG. 1D, at a level higher than an upper surface of the upper protective layer 130, a first width W1 of the first connection bump 210a may be greater than a second width W2 of the second connection bump 210b. The first width W1 and the second width W2 may be defined as a maximum horizontal width of any same level on a level higher than the upper surface of the upper protective layer 130. The first group of connection bumps 210a and the second group of connection bumps 210b may have the same or similar characteristics, except when separately distinguished and described.

Each connection pillar 220 of the plurality of connection bumps 210 may be in contact with the first surface 200S of the semiconductor chip 200. Although not specifically illustrated, a connecting via extending into an interior of the semiconductor chip 200 may be further disposed on the upper surface of the connection pillar 220, and the connection pillar 220 may be electrically connected to interconnection lines and semiconductor devices inside the semiconductor chip 200 through the connecting via. Referring to FIG. 1C, a lower surface and a side surface of the first connection pillar 220a may be covered by the first connection solder 230a. The side surface of the first connection pillar 220a may be separated from the encapsulant 300 by the peripheral portion 230a_2 of the first connection solder 230a. The first connection pillar 220a may not be in contact with the encapsulant 300 by the first connection solder 230a. A lower surface of the second connection pillar 220b may be covered by the second connection solder 230b. At least a portion of the side surface of the second connection pillar 220b may not be covered by the second connection solder 230b, and the side surface of the second connection pillar 220b may be in contact with the encapsulant 300. Due to the warpage of the package substrate body 110, a first gap G1 between a lower surface of the first connection pillar 220a and the upper surface of the first upper connecting pad 120a may be less than a second gap G2 between the lower surface of the second connection pillar 220b and an upper surface of the second upper connecting pad 120b. The first connection pillar 220a and the second connection pillar 220b may have substantially the same or similar shapes. The connection pillar 220 may include a conductive material, and may include, for example, at least one metal material of aluminum (Al), copper (Cu), nickel (Ni), tungsten (W), platinum (Pt), or gold (Au).

The connection solder 230 of each of the plurality of connection bumps 210 may be disposed between the connection pillar 220 and the upper connecting pad 120. The connection solder 230 may cover a lower surface of the connection pillar 220 and an upper surface of the upper connecting pad 120. The first connection solder 230a and the second connection solder 230b may have different shapes. The first connection solder 230a may include a bonded portion 230a_1 between the first connection pillar 220a and the first upper connecting pad 120a, and a peripheral portion 230a_2 surrounding a side surface of the first connection pillar 220a. The peripheral portion 230a_2 may cover at least a portion of the side surface of the first connection pillar 220a, and may separate the first connection pillar 220a and the encapsulant 300 so that the first connection pillar 220b and the encapsulant 300 are not in contact with each other. The peripheral portion 230a_2 of the first connection solder 230a may be in contact with the first surface 200S. In example embodiments, a first thickness T1 of the peripheral portion 230a_2 covering the first connection pillar 220a may be less than the first gap G1. The second connection solder 230b may cover the lower surface of the second connection pillar 220b and the upper surface of the second upper connecting pad 120b. The second connection solder 230b may not cover the side surface of the second connection pillar 220b. The second connection solder 230b may be spaced apart from the first surface 200S. A contact area between the first connection solder 230a and the first connection pillar 220a may be greater than a contact area between the second connection solder 230b and the second connection pillar 220b. In example embodiments, a contact area between the first connection solder 230a and the upper protective layer 130 may be greater than a contact area between the second connection solder 230b and the upper protective layer 130. An upper end of the second connection solder 230b may be disposed on a level lower than an upper end of the first connection solder 230a. The upper end of the first connection solder 230a may be disposed closer to the first surface 200S of the semiconductor chip 200 than the upper end of the second connection solder 230b. A volume of the first connection solder 230a may be greater than a volume of the second connection solder 230b. In example embodiments, a level difference between the upper end and the lower end of the first connection solder 230a may be greater than a level difference between the upper end and the lower end of the second connection solder 230b. A maximum planar area of the first connection solder 230a may be greater than a maximum planar area of the second connection solder 230b. The connection solder 230 may include a conductive material, and may include, for example, a low melting point metal such as tin (Sn), indium (In), bismuth (Bi), antimony (Sb), copper (Cu), silver (Ag), zinc (Zn), lead (Pb), or alloys containing these metals (for example, Sn—Ag—Cu).

The encapsulant 300 may surround the semiconductor chip 200 and the plurality of connection bumps 210 on the package substrate 100. The encapsulant 300 may encapsulate at least a portion of the semiconductor chip 200. An upper surface of the encapsulant 300 may be disposed on a level higher than an upper surface of the semiconductor chip 200. The encapsulant 300 may cover the first surface, the upper surface, and the side surface of the semiconductor chip 200. In example embodiments, the encapsulant 300 may have a capillary underfill (CUF) structure further including an underfill surrounding the plurality of connection bumps 210 between the semiconductor chip 200 and the package substrate 100. In example embodiments, the encapsulant 300 may have a molded underfill (MUF) structure integrated with the underfill. The encapsulant 300 may physically and chemically protect the package substrate 100, the semiconductor chip 200 and the plurality of connection bumps 210 from the outside. The encapsulant 300 may include, for example, a thermosetting resin such as an epoxy resin, a thermoplastic resin such as a polyimide, or a prepreg, ABF, FR-4, BT, Epoxy Molding Compound (EMC). In example embodiments, the encapsulant 300 may be omitted.

In the following description, any description overlapping the description made with reference to FIGS. 1A to 1D will be omitted.

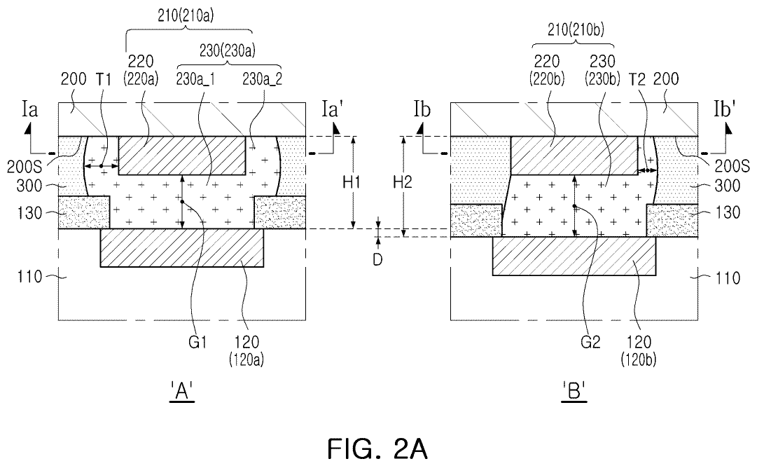

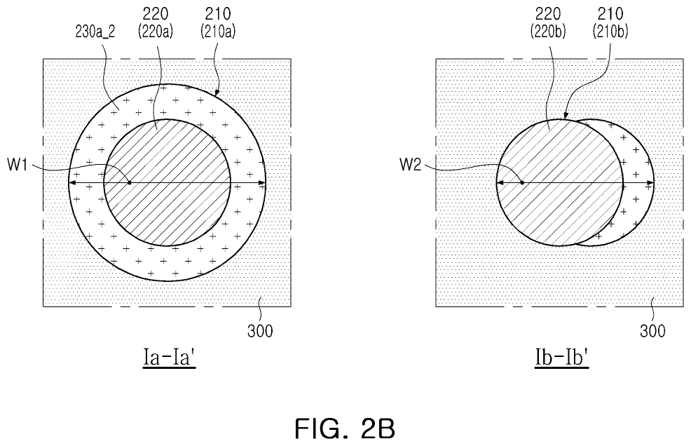

FIG. 2A is a schematic partial enlarged cross-sectional view illustrating a semiconductor package according to example embodiments. FIG. 2A illustrates regions corresponding to region ‘A’ and region ‘B’ of FIG. 1C.

FIG. 2B is a schematic partial enlarged plan view illustrating a semiconductor package according to example embodiments. FIG. 2B schematically illustrates cross-sections taken along the cutting lines Ia-Ia′ and Ib-Ib′ of region ‘A’ of FIG. 2A.

Referring to FIGS. 2A and 2B, unlike example embodiments of FIGS. 1C and 1D, the second connection solder 230b of the second connection bump 210b may cover a portion of the side surface of the second connection pillar 220b, and may be in contact with the first surface 200S of the semiconductor chip 200. A portion of the side surface of the second connection pillar 220b may be in contact with the second connection solder 230b, and the remainder thereof may be in contact with the encapsulant 300. The first thickness T1 of the peripheral portion 230a_2 of the first connection solder 230a covering the side surface of the first connection pillar 220a may be greater than a second thickness T2 of the second connection solder 230b covering the side surface of the second connection pillar 220b. The first width W1 may be greater than the second width W2 of a second connection bump 200b. The first width W1 and the second width W2 may be maximum horizontal widths of each of the first connection pillar 220a and the second connection pillar 220b on any level higher than that of the upper surface of the upper protective layer 130. As with example embodiments of FIGS. 1C and 1D, the first width W1 of the first connection bump 210a may be greater than the second width W2 of the second connection bump 210b.

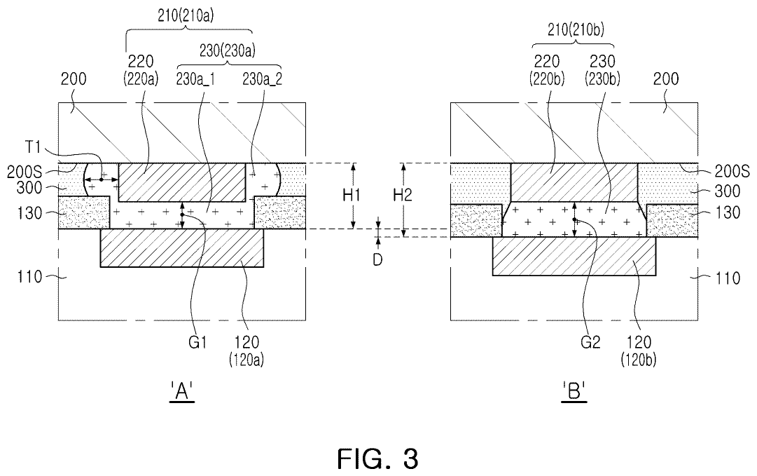

FIG. 3 is a schematic partial enlarged cross-sectional view illustrating a semiconductor package according to example embodiments. FIG. 3 illustrates regions corresponding to region ‘A’ region and region ‘B’ region of FIG. 1C.

Referring to FIG. 3, unlike example embodiments of FIG. 1C, a maximum first thickness T1 by which the peripheral portion 230a_2 of the first connection solder 230a covers the side surface of the first connection pillar 220a may be greater than the first gap G1 between the lower surface of the first connection pillar 220a and the upper surface of the first upper connecting pad 120a. Depending on the volume of the first connection solder 230a, the size of the first separation distance H1 between the first surface 200S and the upper surface of the package substrate body 110, and the like, the shape in which the first connection solder 230a surrounds the side surface of the first connection pillar 220a may be modified. In example embodiments, the lower surface of the first connection pillar 220a may be disposed on a level lower than that of the upper surface of the upper protective layer 130, and the lower surface of the second connection pillar 220b may be disposed on a level higher than the upper surface of the upper protective layer 130. In example embodiments, unlike what is illustrated, the lower surface of the second connection pillar 220b may be disposed on a level lower than the upper surface of the upper protective layer 130.

Depending on the warpage of the package substrate body 110, a distance between the first surface 200S and the upper surface of the package substrate 100 may vary depending on the position thereof. At least some of the forms of example embodiments of FIGS. 1C and 1D, 2A and 2B, and 3 may be applied to the plurality of connection bumps 210 included in the semiconductor package 10A. Each of the connection bumps 210a of the first group may have one of the characteristics of example embodiments of region ‘A’ illustrated in FIGS. 1C and 1D, 2A and 2B, and 3. Each of the connection bumps 210b of the second group may have one of the characteristics of example embodiments of region ‘B’ region illustrated in FIGS. 1C and 1d, 2A and 2B, and 3. Unlike the second connection solders 230b, the first connection solders 230a may include a peripheral portion 230a_2, and example embodiments may be variously modified within the range to which these characteristics are applied.

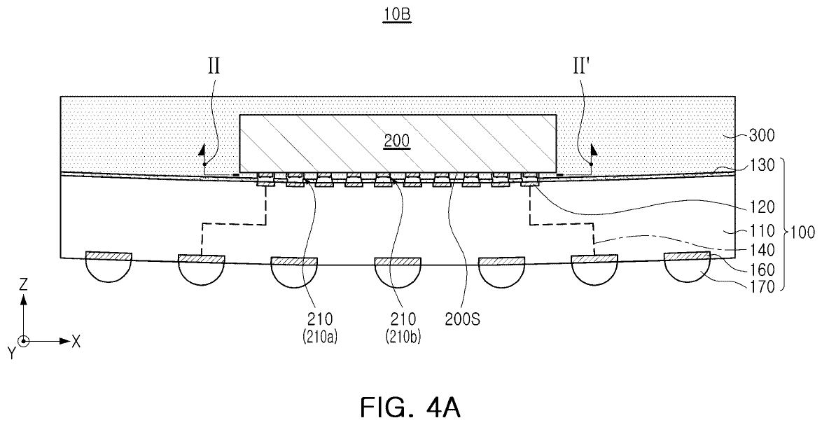

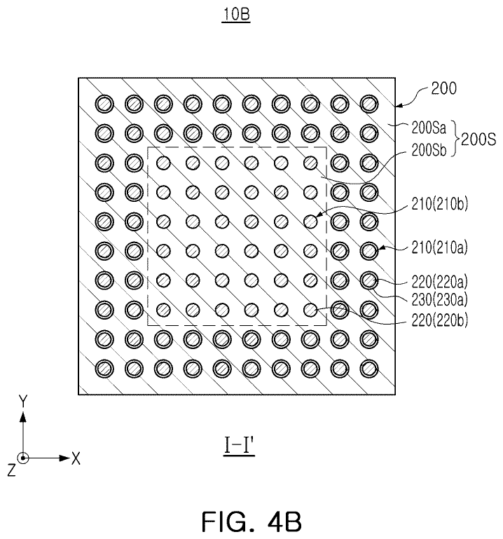

FIG. 4A is a schematic cross-sectional view illustrating a semiconductor package according to example embodiments.

FIG. 4B is a schematic plan view illustrating a semiconductor package according to example embodiments. FIG. 4B schematically illustrates a cross-section taken along the cutting line II-II′ of FIG. 4A. FIG. 4B schematically illustrates the shape of the first surface 200S of the semiconductor chip 200.

Referring to FIGS. 4A and 4B, unlike the semiconductor package 10A of FIGS. 1A and 1B, a semiconductor package 10B may have warpage in the form in which an edge of a package substrate body 110 is bent upwardly. That is, a separation distance between a central portion of the first surface 200S and the upper surface of the package substrate body 110 may be greater than a separation distance between an edge of the first surface 200S and the upper surface of the package substrate body 110. In this case, unlike the semiconductor package 10A of FIGS. 1A and 1B, the first region 200Sa in which the first group of connection bumps 210a are disposed may be disposed at the edge of the first surface 200S, and the second region 200Sb in which the second group of connection bumps 210b are disposed may be disposed in the central portion of the first surface 200S. In the vertical direction, the edge of the first surface 200S may include a portion in which a separation distance from the upper surface of the package substrate 100 is less than that of the second region 200Sb. The second region 200Sb may be disposed on an inner side of the first surface 200S, and the first region 200Sa may surround the second region 200Sb. The first group of connection bumps 210a may be disposed in a form surrounding the second group of connection bumps 210b. Referring to FIG. 1C and FIG. 1D together, the first group of connection bumps 210a disposed in the first region 200Sa having a relatively small separation distance from the upper surface of the package substrate body 110 may include the peripheral portion 230a_2. Since the first group of connection bumps 210a include the peripheral portion 230a_2, the second group of connection bumps 210b disposed in the second region 200Sb having a relatively large separation distance from the upper surface of the package substrate body 110 may be induced to be stably connected to the second upper connection pads 120b.

In FIG. 1A and FIG. 1B, an example of a case where a warpage is formed in a shape in which the edge of the package substrate body 110 is bent downwardly is described, and in FIG. 4A and FIG. 4B, an example of a case in which a warpage is formed in a shape in which the edge of the package substrate body 110 is bent upwardly is described. Even if the shapes of the warpages are different, the package substrate bodies 110 have the common characteristics in that the first group of connection bumps 210a are formed in the first region 200Sa having a relatively close vertical distance to the upper surface of the package substrate body 110 on the first surface 200S, and the second group of connection bumps 210b are formed in the second region 200Sb having a relatively distant vertical distance to the upper surface of the package substrate body 110. Since each of the connection bumps 210a of the first group includes the first connection solder 230a including the peripheral portion 230a_2, the second group of connection bumps 210b disposed in the second region 200Sb may also be induced to be stably bonded to the second upper connection pads 120b.

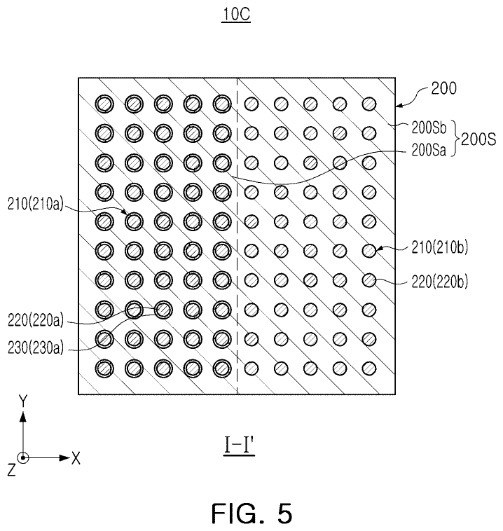

The warpage shape of the package substrate body 110 may occur in various forms in addition to the shape of the semiconductor package 10A of FIGS. 1A and 1B and the shape of the semiconductor package 10B of FIGS. 4A and 4B. For example, the warpage may occur in a wave shape or may occur in various forms, such as a form in which only one side surface of the package substrate body 110 is bent upwardly or downwardly. Depending on the warpage shape of the package substrate body 110, positions, areas, and the like, of the first region 200Sa and the second region 200Sb within the first surface 200S may be variously modified and defined, and the number, positions, and the like, of the first group of connection bumps 210a and the second group of connection bumps 210b may also be variously modified. In the following description referring to FIGS. 5 to 7, examples of such modifications will be described.

FIGS. 5 to 7 are schematic plan views illustrating semiconductor packages according to example embodiments. FIGS. 5 to 7 illustrate regions corresponding to FIGS. 1B and 4B, and schematically illustrate the shape of the first surface 200S of the semiconductor chip 200.

Referring to FIG. 5, unlike example embodiments of FIGS. 1B and 4B, in a semiconductor package 10C, the first region 200Sa may be disposed on one side of the first surface 200S, and the second region 200Sb may be disposed on the other side thereof. Referring to FIGS. 1A and 4A together, when a warpage occurs in a form in which one side of the package substrate body 110 is bent upwardly or bent downwardly, the first region 200Sa and the second region 200Sb may be disposed in parallel within the first surface 200S. Accordingly, the first group of connection bumps 210a may be disposed on one side of the first surface 200S, and the second group of connection bumps 210b may be disposed on the other side of the first surface 200S. The connection bumps 210a of the first group and the connection bumps 210b of the second group may be disposed so as to overlap each other in the first direction (e.g., X-direction) but not overlap each other in the second direction (e.g., Y-direction), intersecting the first direction.

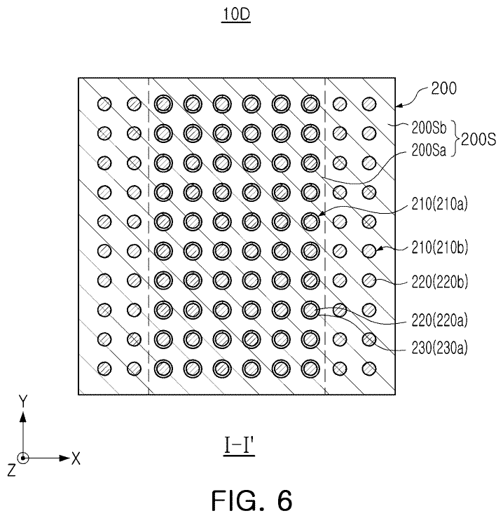

Referring to FIG. 6, in a semiconductor package 10D, unlike the semiconductor package 10A of FIG. 1B, the second region 200Sb in which the second group of connection bumps 210b are disposed may be disposed on both sides of the first region 200Sa in which the first group of connection bumps 210a are disposed. In the first direction (e.g., X-direction), parallel to the first surface 200S, the connection bumps 210a of the first group may be disposed between the connection bumps 210b of the second group. In the second direction (e.g., Y-direction), intersecting the first direction, the connection bumps 210a of the first group may not overlap the connection bumps 210b of the second group. Referring to FIG. 1A together, when a warpage in which an edge portion of the package substrate body 110 is bent downwardly in the first direction, and the warpage does not occur or is relatively weak in the second direction, example embodiments such as the semiconductor package 10D of FIG. 6 may be applied thereto. Although not illustrated in a separate drawing, when the package substrate body 110 has a warpage in which the edge thereof is bent upwardly in the first direction, the first region 200Sa and the second region 200Sb may be disposed opposite to those illustrated in FIG. 6, and the first group of connection bumps 210a and the second group of connection bumps 210b may also be disposed opposite to those illustrated in FIG. 6.

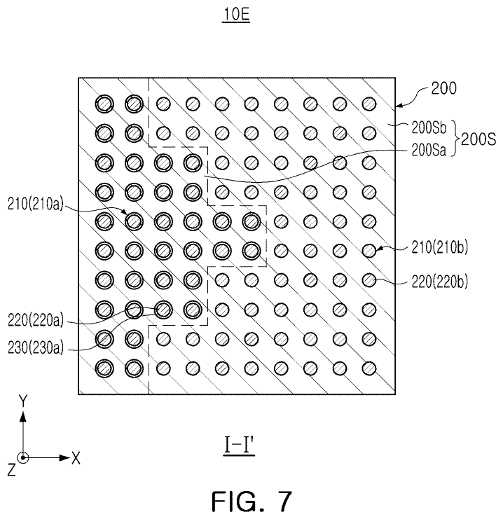

Referring to FIG. 7, unlike example embodiments of FIGS. 1B and 4B, in a semiconductor package 10E, the first region 200Sa in which the first group of connection bumps 210a are disposed and the second region 200Sb in which the second group of connection bumps 210b are disposed may be disposed in different patterns. When the warpage of the package substrate body 110 occurs so that one outer surface of the package substrate body 110 is bent upwardly, and both outer surfaces adjacent to the one surface are also affected by the warpage, the same example embodiment as an arrangement pattern of the first group of connection bumps 210a of this example embodiment may be applied thereto.

The first region 200Sa in which the first group of connection bumps 210a of the first surface 200S of the semiconductor chip 200 are disposed and the second region 200Sb in which the second group of connection bumps 210b are disposed may be variously modified according to the warpage occurring in a portion overlapping the first surface 200S of the package substrate 100. Example embodiments illustrated in FIGS. 1A to 7 are exemplary illustrations according to the shape of the warpage of the package substrate 100. Various example embodiments may be applied within a range in which the principle that the first group of connection bumps 210a are disposed in the first region 200Sa relatively close to the upper surface of the package substrate 100 among the first surface 200S and the second group of connection bumps 210b are disposed in the second region 200Sb relatively distant away therefrom is applied.

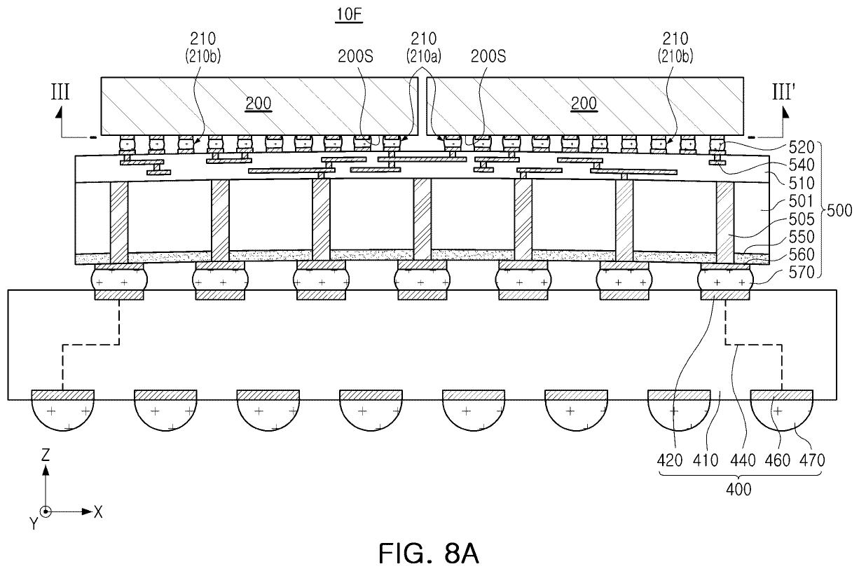

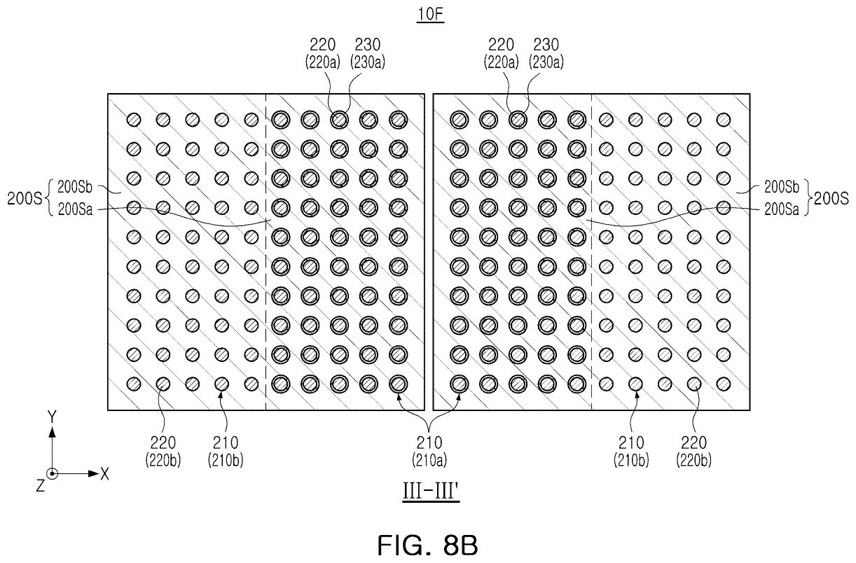

FIG. 8A is a schematic cross-sectional view illustrating a semiconductor package according to example embodiments.

FIG. 8B is a schematic plan view illustrating a semiconductor package according to example embodiments. FIG. 8B schematically illustrates a cross-section taken along the cutting line III-III′ of FIG. 8A. FIG. 8B schematically illustrates the shape of the first surface 200S of the semiconductor chips 200.

Referring to FIG. 8A, a semiconductor package 10F may include a plurality of semiconductor chips 200, and an interposer substrate 500 may be disposed between the plurality of semiconductor chips 200 and the package substrate 400.

The package substrate 400 of this example embodiment may have the features identical to or similar to the package substrate 100 of the semiconductor package 10A of FIGS. 1A to 1D, except for the contents described separately. The package substrate 400 of example embodiments may include a package substrate body 410, upper connection pads 420, an interconnection circuit 440, lower connection pads 460, and external connection conductors 470, which correspond to each component of the package substrate 100 of the semiconductor package 10A of FIGS. 1A to 1D. The package substrate 400 may be a support substrate on which the interposer substrate 500 is mounted, and any description overlapping the package substrate 100 of the semiconductor package 10A of FIGS. 1A to 1D will be omitted.

The interposer substrate 500 may include an interposer substrate body 501, a through-via 505, an upper insulating layer 510, interposer connection pads 520, rewiring patterns 540, a lower insulating layer 550, a conductive pad 560, and a conductive bump 570. In example embodiments, unlike the one illustrated, the interposer substrate 500 may include a silicon bridge electrically connecting the semiconductor chips 200.

The interposer substrate body 501 may be formed of, for example, any one of a silicon, organic, plastic, and glass substrate. When the interposer substrate body 501 is a silicon substrate, the interposer substrate 500 may be referred to as a silicon interposer. When the interposer substrate body 501 is an organic substrate, unlike the one illustrated in the drawing, the interposer substrate 500 may be referred to as a panel interposer or an organic interposer.

The interposer substrate body 501 may have a warpage according to example embodiments. In example embodiments, as illustrated in FIG. 8A, an edge of the interposer substrate body 501 may be partially warped downwardly. The shape, degree, and the like, of the warpage of the interposer substrate body 501 may be variously modified according to example embodiments, and in the description referring to FIGS. 8A and 8B, example embodiments in which the edge of the interposer substrate body 501 is warped downwardly is described. Depending on the warpage occurring in the interposer substrate body 501, a gap between the upper surface of the interposer substrate 500 and the first surface 200S of each of the semiconductor chips 200 may not be constant. A separation distance between the first region 200Sa of the first surface 200S of each of the semiconductor chips 200 and the upper surface of the interposer substrate 500 may be less than a separation distance between the second region 200Sb of the first surface 200S and the upper surface of the interposer substrate 500. The description of an arrangement relationship between the package substrate 100 of the semiconductor package 10A of FIGS. 1A to 1D and the semiconductor chip 200 may be similarly applied to an arrangement relationship between the interposer substrate 500 and the semiconductor chips 200 caused by the warpage of the interposer substrate body 501.

The lower insulating layer 550 may be disposed on the lower surface of the interposer substrate body 501, and the conductive pad 560 may be disposed below the lower insulating layer 550. The conductive pad 560 may be connected to the through-via 505. The semiconductor chips 200 may be electrically connected to the package substrate 400 through metal bumps 720 disposed below the conductive pads 560.

The upper insulating layer 510 may be disposed on an upper surface of the interposer substrate body 501. An upper surface of the upper insulating layer 510 may not have a constant separation distance from the first surface 200S of the semiconductor chips 200 due to the warpage of the interposer substrate body 501. In example embodiments, the second region 200Sb of the first surface 200S of each of the semiconductor chips 200 may have a greater separation distance from the upper surface of the upper insulating layer 510 than the first region 200Sa of the first surface 200S. Interposer connection pads 520 may be disposed on the upper insulating layer 510. The interposer connection pads 520 may have the characteristics identical to or similar to the upper connection pads 120 of FIGS. 1A to 1D. The rewiring patterns 540 may be disposed within the upper insulating layer 510. The rewiring patterns 540 may include a single-layer or multilayer interconnection structure. When the rewiring patterns 540 are formed of a multi-layer interconnection structure, the interconnection patterns of different layers may be connected to each other through a contact via.

The through-via 505 may extend from the upper surface to the lower surface of the interposer substrate body 501 and may penetrate through the interposer substrate body 501. In addition, the through-via 505 may extend into the interior of the rewiring patterns 540 and may be electrically connected to wirings of the rewiring patterns 540. When the interposer substrate body 501 is formed of silicon, the through-via 505 may be referred to as a TSV. According to example embodiments, the interposer substrate 500 may only include an interconnection structure therein and may not include a through-via.

The interposer substrate 500 may be used for the purpose of converting or transmitting an input electrical signal between the package substrate 400 and the semiconductor chips 200. Accordingly, the interposer substrate 500 may not include components such as active components or passive components. In addition, according to example embodiments, the rewiring patterns 540 may be disposed in a lower portion of the through-via 505. For example, a positional relationship between the rewiring patterns 540 and the through-via 505 may be relative.

The conductive bump 570 may electrically connect the interposer substrate 500 and a package substrate 900. The semiconductor chips 200 may be electrically connected to the conductive bumps 570 through the wirings of the rewiring patterns 540 and the through-vias 505. According to example embodiments, the conductive pads 560 used for power or ground may be integrated and connected together to the conductive bumps 570, so that the number of the conductive pads 560 may be greater than the number of the conductive bumps 570.

The semiconductor chips 200 may be disposed on the interposer substrate 500. In example embodiments, the semiconductor chips 200 may include different types of chips. For example, the semiconductor chips 200 may include a semiconductor chip including a logic chip and a semiconductor chip including a memory chip. The semiconductor chips 200 may have the same or similar characteristics as the semiconductor chips 200 of FIGS. 1A to 1D.

The plurality of connection bumps 210 may be disposed between the semiconductor chips 200 and the interposer connection pads 520 of the interposer substrate 500. The plurality of connection bumps 210 may include a first group of connection bumps 210a and a second group of connection bumps 210b. Similarly to the semiconductor package 10A of FIGS. 1A to 1D, the first group of connection bumps 210a may be disposed in the first region 200Sa of the first surface 200S, relatively close to the upper surface of the interposer substrate 500, and the second group of connection bumps 210b may be disposed in the second region 200Sb of the first surface 200S, relatively distant from the upper surface of the interposer substrate 500. The semiconductor chips 200 may be induced to be mounted closer to the upper surface of the interposer substrate 500 by the peripheral portion 230a_2 of the first connection solder 230a included in each of the connection bumps 210a of the first group, and the second group of connection bumps 210b may stably connect the interposer connection pads 520 of the interposer substrate 500. Accordingly, the reliability of the semiconductor package 10F including the interposer substrate 500 may be improved. Since FIGS. 8A and 8B exemplarily illustrate example embodiments of a warpage shape of the interposer substrate 500, arrangement forms of the first group of connection bumps 210a and the second group of connection bumps 210b may be variously modified depending on the warpage shape of the interposer substrate 500.

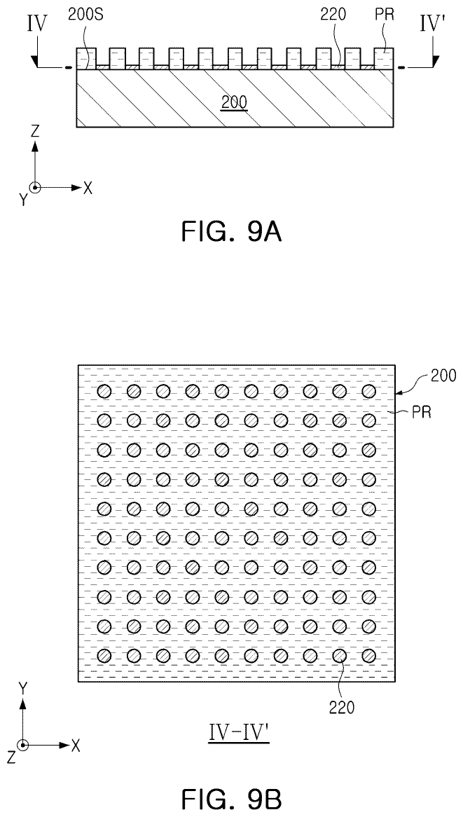

FIGS. 9A, 10A, 11A and 12A are cross-sectional views illustrating a manufacturing method of a semiconductor package according to example embodiments in accordance with a process sequence. FIGS. 9A, 10A, 11A and 12A are cross-sectional views illustrating a manufacturing method of a plurality of connection bumps 210 on a first surface 200S of a semiconductor chip 200 of a semiconductor package 10A of FIGS. 1A to 1D.

FIGS. 9B, 10B, 11B and 12B are plan views illustrating a manufacturing method of a semiconductor package according to example embodiments in accordance with a process sequence. FIGS. 9B, 10B, 11B and 12B schematically illustrate cross-sections taken along the cutting line IV-IV′ of FIGS. 9A, 10A, 11A and 12A, respectively.

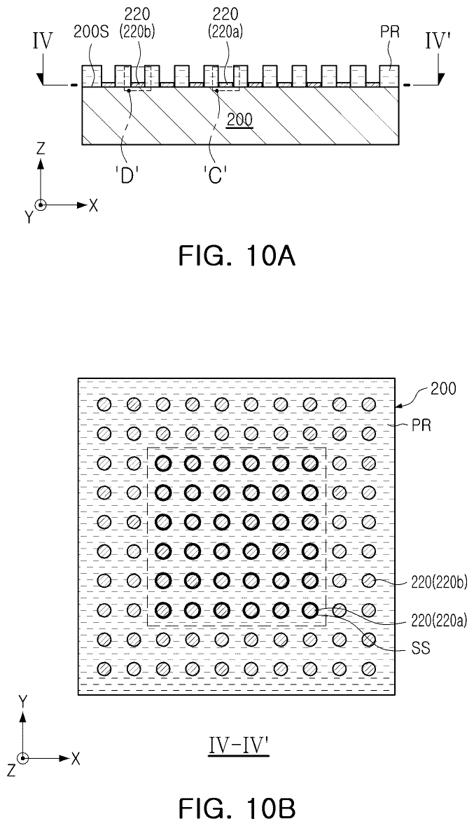

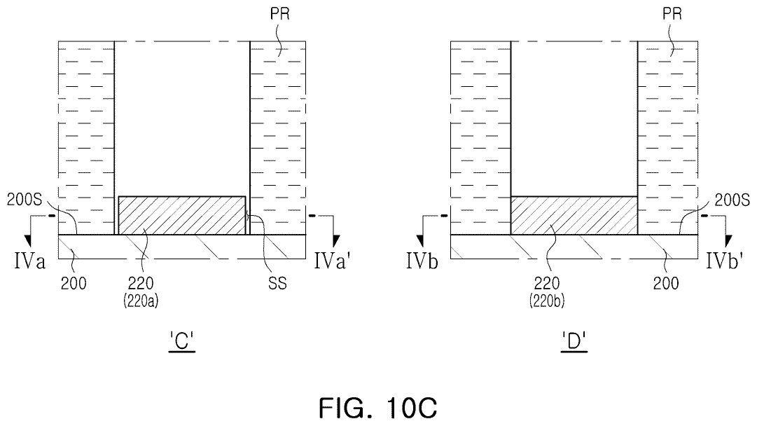

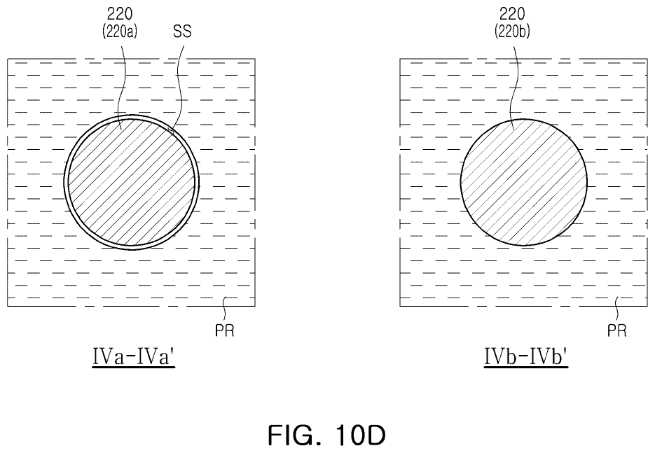

FIGS. 10C, 11C and 12C are partially enlarged cross-sectional views illustrating a manufacturing method of a semiconductor package according to example embodiments in accordance with a process sequence. FIGS. 10C, 11C and 12C illustrate region ‘C’ and region ‘D’ of FIGS. 10A, 11A and 12A in an enlarged manner, respectively. Region ‘C’ illustrates example embodiments of a manufacturing method of the first group of connection bumps 210a, and region ‘D’ illustrates example embodiments of a manufacturing method of the second group of connection bumps 210b.

FIGS. 10D, 11D and 12D are partially enlarged plan views illustrating a manufacturing method of a semiconductor package according to example embodiments in accordance with a process sequence. FIGS. 10D, 11D and 12D schematically illustrate cross sections taken along the cutting lines IVa-IVa′ and IVb-IVb′ of FIGS. 10C, 11C and 12C, respectively.

Referring to FIGS. 9A and 9B, a plurality of connection pillars 220 may be formed on the first surface 200S of the semiconductor chip 200.

Referring also to FIG. 1A, the semiconductor chip 200 may include a first surface 200S on which a plurality of connection bumps 210 are disposed. After forming a photoresist pattern PR exposing a region in which a plurality of connection pillars 220 are to be formed on the first surface 200S, a plurality of connection pillars 220 may be formed on the first surface 200S exposed from the photoresist pattern PR. The plurality of connection pillars 220 may have a cylindrical or polygonal pillar shape. In example embodiments, the plurality of connection pillars 220 may be formed by a plating process such as electrolytic plating. In example embodiments, the plurality of connection pillars 220 may include a seed layer in contact with the first surface 200S, and the seed layer may be formed by a plating process, a Physical Vapor Deposition (PVD) process, or a Chemical Vapor Deposition (CVD) process. The photoresist pattern PR may be formed on the seed layer after the seed layer is formed.

Referring to FIGS. 10A, 10B, 10C and 10D, side spaces SS exposing side surfaces of the first connection pillars 220a may be formed.

The side spaces SS may be formed by partially removing the photoresist pattern PR to expose the side surfaces of the first connection pillars 220a, among the plurality of connection pillars 220. In example embodiments, the side spaces SS may be formed by patterning a portion of the photoresist pattern PR surrounding the side surfaces of the first connection pillars 220a. The photoresist pattern PR may be in contact with the side surfaces of the second connection pillars 220b. The photoresist pattern PR may be spaced apart from the side surfaces of the first connection pillars 220a by the side spaces SS. In example embodiments, after forming the plurality of connection pillars 220, all of the existing photoresist patterns PR may be removed, and a new photoresist pattern PR may be formed so that side spaces SS are formed on the side surfaces of the first connection pillars 220a.

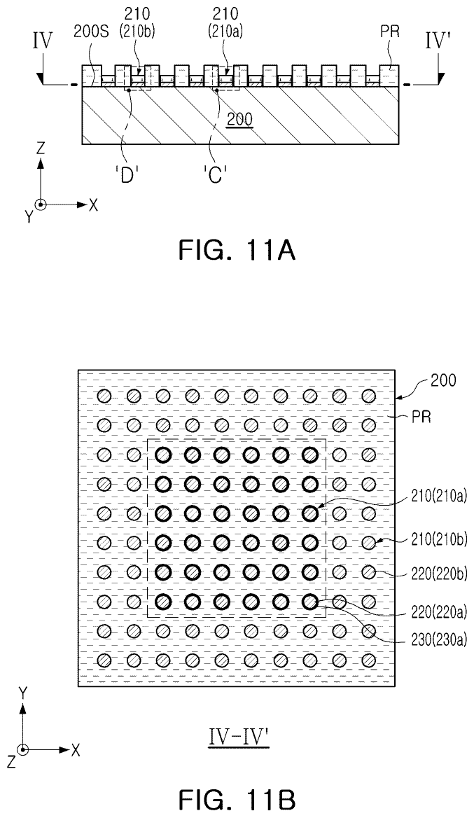

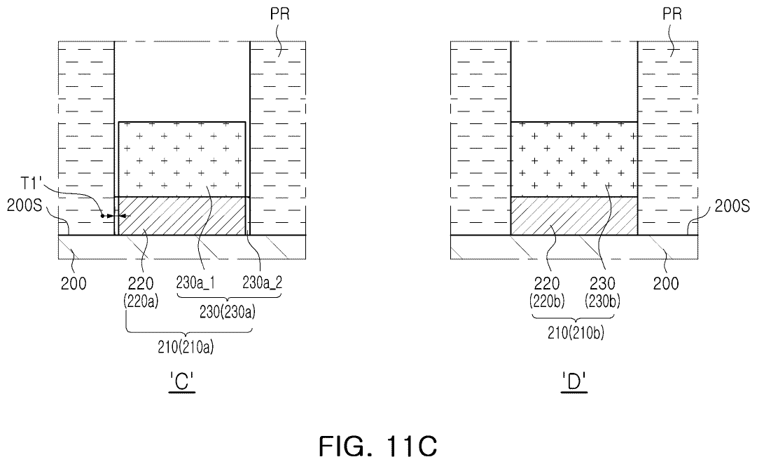

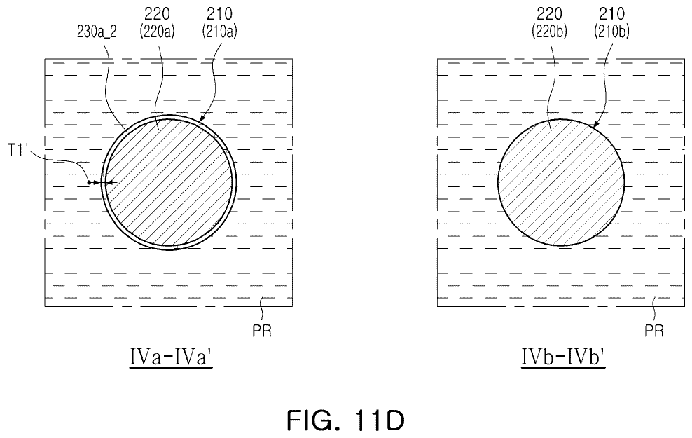

Referring to FIGS. 11A, 11B, 11C and 11D, connection solders 230 may be formed to form a plurality of connection bumps 210.

The connection solders 230 may be formed on the connection pillars 220 in a plating process such as electroplating. The first connection solders 230a may be formed on side surfaces and upper surfaces of the first connection pillars 220a, and the second connection solders 230b may be formed on upper surfaces of the second connection pillars 220b. The first connection solders 230a may include a bonded portion 230a_1 formed on the upper surface of the first connection pillars 220a and a peripheral portion 230a_2 formed on the side surfaces of the first connection pillars 220a. The peripheral portion 230a_2 may be formed to fill the side spaces SS on the side surfaces of the first connection pillars 220a, and may be formed to have a first preliminary thickness T1′. Referring to FIG. 1C together, the first preliminary thickness T1′ may be less than the first thickness T1.

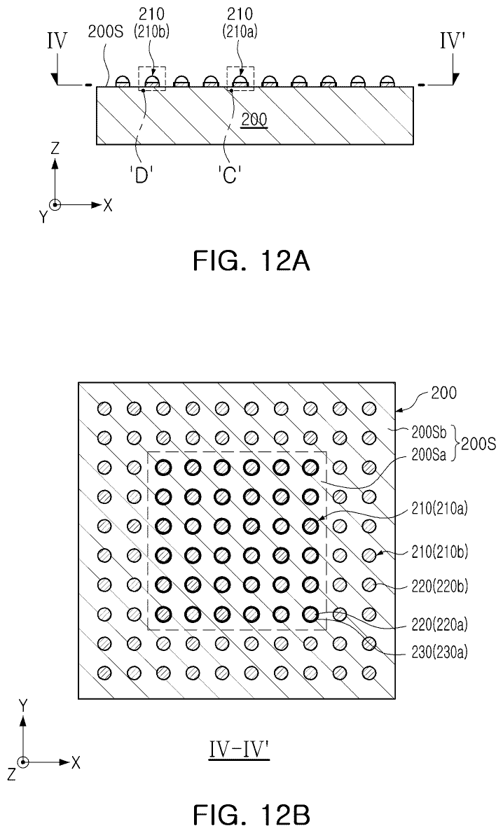

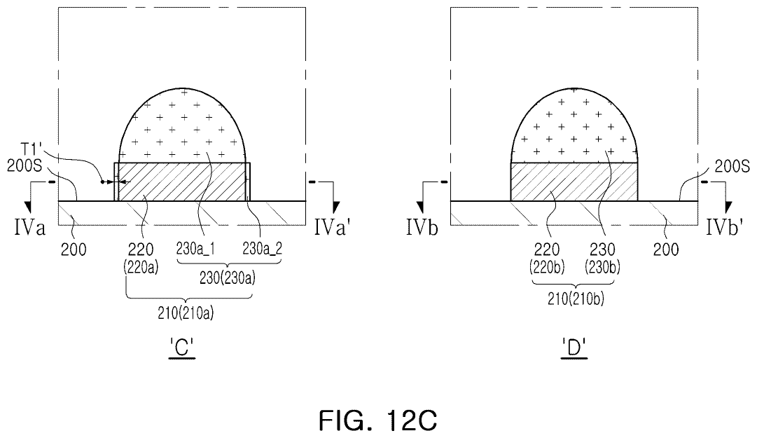

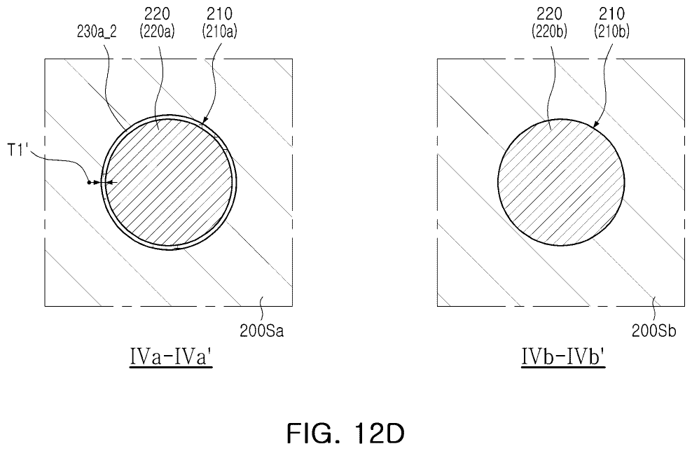

Referring to FIGS. 12A, 12B, 12C and 12D, the photoresist pattern PR may be removed and the connection solders 230 may be formed in the form of a solder ball in a reflow process, or the like.

The photoresist pattern PR may be removed, for example, by performing an ashing process. The photoresist pattern PR may be removed to expose the first surface 200S. The first surface 200S may include a first region 200Sa in which the first group of connection bumps 210a are disposed and a second region 200Sb in which the second group of connection bumps 210b are disposed. The connection solders 230 may be formed in the form of a solder ball through a reflow process performed at a temperature at which the connection solders 230 are melted, for example, at about 200° C. or higher. In FIG. 12C, the bonded portion 230a_1 and the peripheral portion 230a_2 of the first connection solder 230a are illustrated as being separated, but the present disclosure is not limited thereto. In example embodiments, after the reflow process, the bonded portion 230a_1 may be formed in a form covering an upper end of the peripheral portion 230a_2.

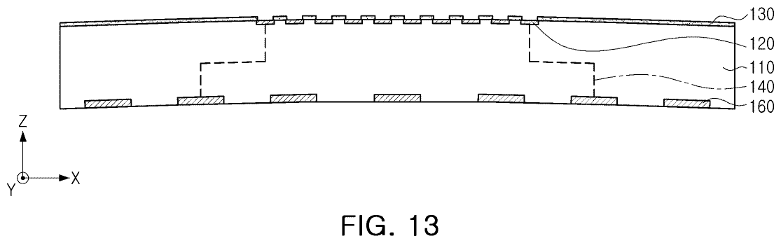

FIGS. 13, 14A, 15A and 16 are cross-sectional views illustrating a manufacturing method of a semiconductor package according to example embodiments in accordance with the process sequence. FIGS. 13, 14A, 15A and 16 illustrate regions corresponding to FIG. 1A.

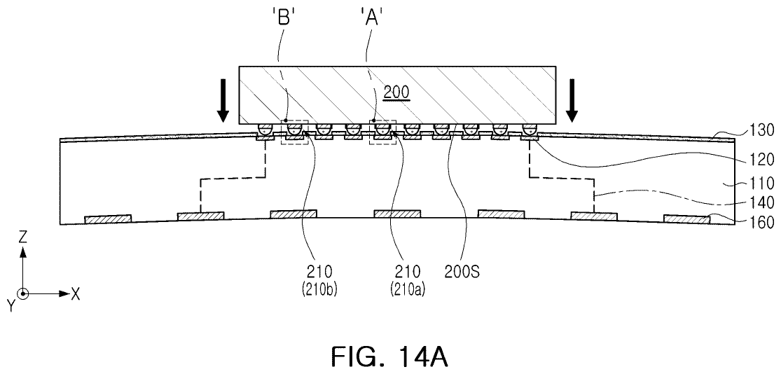

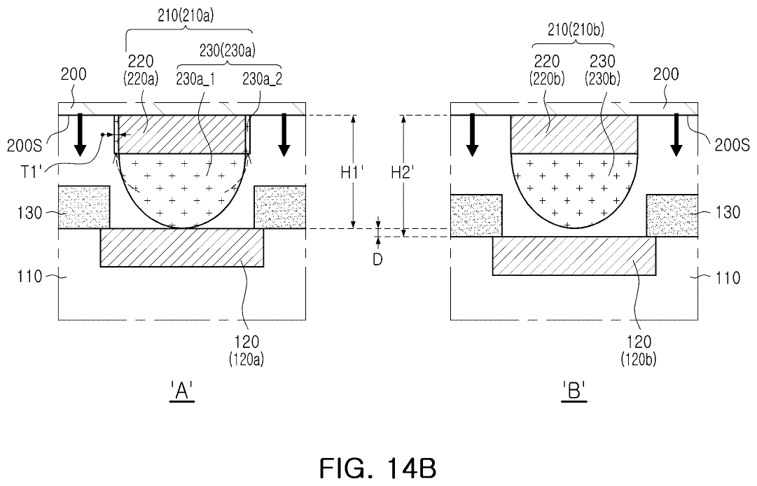

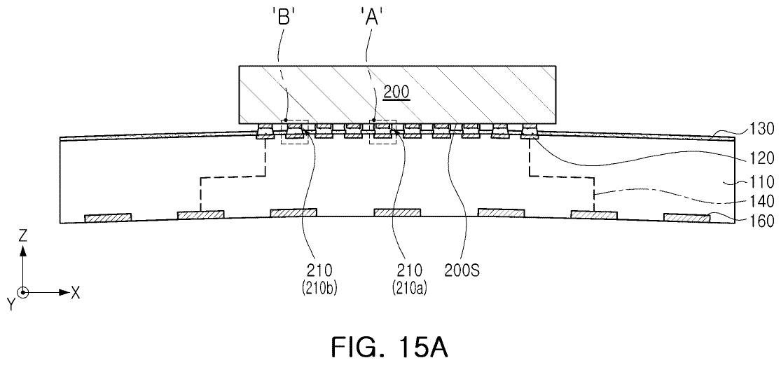

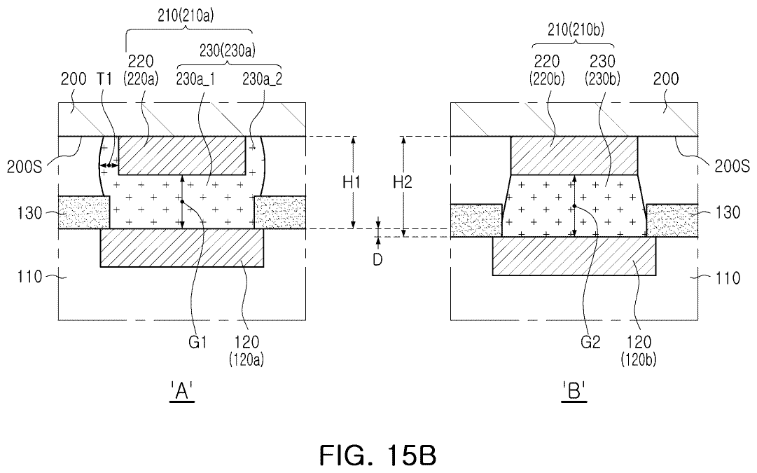

FIGS. 14B and 15B are partially enlarged cross-sectional views illustrating a manufacturing method of a semiconductor package according to example embodiments in accordance with the process sequence. FIGS. 14B and 15B illustrate regions ‘A’ and ‘B’ of FIGS. 14B and 15B in an enlarged manner, respectively, and illustrate regions corresponding to FIG. 1C.

Referring to FIG. 13, a package substrate body 110 including an interconnection circuit 140 may be prepared.

A warpage may be formed on the package substrate body 110. For example, the warpage may be formed on the package substrate body 110 so that an edge of a side surface thereof is bent downwardly. The warpage of the package substrate body 110 may occur in various forms, and various example embodiments may be formed according to the warpage shape. For example, unlike that illustrated in FIG. 13, when the warpage is formed so that the edge of the side surface of the package substrate body 110 is bent upwardly, the semiconductor package 10B of FIG. 4A and FIG. 4B may be manufactured according to the subsequent process. Depending on the type of the package substrate body 110, conductive patterns and insulating layers may be repeatedly stacked within the package substrate body 110, conductive vias penetrating through the insulating layer and connecting conductive patterns having different levels may be formed, which may form the interconnection circuit 140. Upper connection pads 120 and an upper protection layer 130 may be formed on the upper surface of the package substrate body 110, and lower connection pads 160 may be formed on the lower surface of the package substrate body 110. In example embodiments, the upper protection layer 130 may be formed by applying a composition material, for example, Photo Solder Resist (PSR) ink and a curing agent to cover the upper surface of the package substrate body 110, and then partially removing the applied composition material so that the upper surface of the upper connection pads 120 is exposed. Although not specifically illustrated, a lower protective layer may be formed on the lower surface of the package substrate body 110 to expose the lower surface of the lower connection pads 160.

Referring to FIGS. 14A and 14B, a semiconductor chip 200 may be disposed on the package substrate body 110. FIGS. 14A and 14B illustrate some processes of mounting the semiconductor chip 200.

The semiconductor chip 200 may be mounted so that the first surface 200S faces the upper surface of the package substrate body 110. A plurality of connection bumps 210 described with reference to FIGS. 9a to 12d may be disposed on the first surface 200S of the semiconductor chip 200. Due to the warpage of the package substrate body 110, a separation distance between the upper surface of the package substrate body 110 and the first surface 200S of the semiconductor chip 200 may not be constant. As illustrated in FIG. 14B, at the moment when the first group of connection bumps 210a is in contact with the first upper connection pads 120a, the second group of connection bumps 210b may still be separated from the second upper connection pads 120b. A second preliminary separation distance H2′ between the second region 200Sb and the upper surface of the package substrate body 110 may be greater than a first preliminary separation distance H1′ between the first region 200Sa and the upper surface of the package substrate body 110. The first preliminary separation distance H1′ may be a separation distance between the upper surface of the package substrate body 110 and the first region 200Sa at the moment when the first connection solder 230a is in contact with the upper surface of the first upper connection pad 120a. A portion of the bonded portion 230a_1 of the first connection solder 230a may be induced toward the peripheral portion 230a_2 during the process of being bonded to the first upper connection pad 120a. The bonded portion 230a_1 of the first connection solder 230a of each of the connection bumps 210a of the first group may be induced to flow toward a side surface of the first connection pillar 220a by the peripheral portion 230a_2 during the bonding process, so that the entire semiconductor chip 200 may be strongly pulled toward the upper surface of the package substrate body 110.

Referring to FIGS. 15A and 15B, a semiconductor chip 200 may be completely mounted on a package substrate body 110.

The first surface 200S of the semiconductor chip 200 may be induced to be disposed close to the upper surface of the package substrate body 110 by the first group of connection bumps 210a. Referring also to FIG. 14B, the first separation distance H1 may be induced to be sufficiently less than the first preliminary separation distance H1′, and the second separation distance H2 may be induced to be sufficiently less than the second preliminary separation distance H2′. As a portion of the bonded portion 230a_1 of the first connection solder 230a is induced toward the peripheral portion 230a_2, the first thickness T1 of the peripheral portion 230a_2 may be formed to be larger than the first preliminary thickness T1′. Even if the second gap G2 between the lower surface of the second connection pillar 220b and the second upper connecting pad 120b is greater than the first gap G1 between the lower surface of the first connection pillar 220a and the first upper connecting pad 120a, the second group of connection bumps 210b may be stably connected to the second upper connecting pads 120b. Accordingly, a semiconductor package having improved reliability and a manufacturing method of a semiconductor package may be provided.

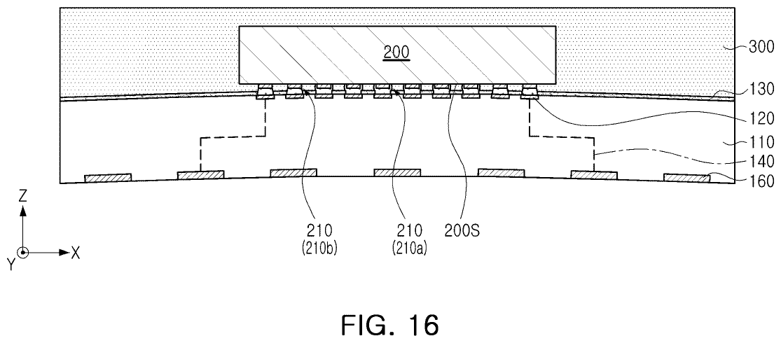

Referring to FIG. 16, an encapsulant 300 may be formed on the package substrate body 110.

The encapsulant 300 may be formed to surround the semiconductor chip 200 and the plurality of connection bumps 210 on the package substrate body 110. In example embodiments, the encapsulant 300 may be formed by partially removing an upper portion from the upper surface of the semiconductor chip 200. In example embodiments, the formation of the encapsulant 300 may be omitted. Hereinafter, referring to FIG. 1A together, the package substrate 100 may be formed by forming external connection conductors 170 below the lower connection pads 160, and the semiconductor package 10A may be manufactured.

A manufacturing method of a semiconductor package according to example embodiments may include: preparing a semiconductor chip having a first surface; forming a photoresist pattern on the first surface; forming a plurality of connection pillars on the first surface, the plurality of connection pillars including first connection pillars and second connection pillars; forming a side space exposing side surfaces of first connection pillars, among the plurality of connection pillars, by removing a portion of the photoresist pattern; and forming a first connection solder on a side surface and an upper surface of each of the first connection pillars and forming a second connection solder on an upper surface of the second connection pillars to form a plurality of connection bumps, wherein the plurality of connection bumps may include a first group of the connection bumps including the first connection pillar and the first connection solder and a second group of the connection bumps including the second connection pillar and the second connection solder.

In the manufacturing method of the semiconductor package according to example embodiments, for each of the first group of the connection bumps, the first connection solder may include a bonded portion covering an upper surface of the first connection pillar and a peripheral portion surrounding a side surface of the first connection pillar.

In the manufacturing method of the semiconductor package according to example embodiments, the peripheral portion of the first connection pillar may entirely cover the side surface of the first connection pillar.

In the manufacturing method of the semiconductor package according to example embodiments, a volume of each of the first group of the connection bumps may be greater than a volume of each of the second group of the connection bumps.

In the manufacturing method of the semiconductor package according to example embodiments, the second group of connection bumps may be disposed to surround the first group of connection bumps.

In the manufacturing method of the semiconductor package according to example embodiments, the first group of connection bumps may be disposed to surround the second group of connection bumps.

In the manufacturing method of the semiconductor package according to example embodiments, a volume of the first connection solder may be greater than a volume of the second connection solder.

The manufacturing method of the semiconductor package according to example embodiments may further include removing the photoresist pattern.

The manufacturing method of the semiconductor package according to example embodiments may further include mounting the semiconductor chip on a package substrate including a plurality of upper connection pads, and the first surface of the semiconductor chip may face an upper surface of the package substrate.

In the manufacturing method of the semiconductor package according to example embodiments, the plurality of upper connection pads may include first upper connection pads connected to the first group of connection bumps and second upper connection pads connected to the second group of connection bumps, and in a vertical direction, substantially perpendicular to the first surface, upper surfaces of at least portions of the first upper connection pads may have a smaller distance from the first surface than upper surfaces of each of the second upper connection pads.

According to example embodiments of the present disclosure, a semiconductor package having improved reliability may be provided by forming a connection solder including a peripheral portion on some of the connection bumps that interconnect the semiconductor chip and the package substrate.

According to example embodiments of the present disclosure, a manufacturing method of a semiconductor package having improved reliability may be provided by forming a connection solder including a peripheral portion on some of the connection bumps that interconnect the semiconductor chip and the package substrate.

The present disclosure is not limited to the above-described embodiments and the accompanying drawings but is defined by the appended claims. Therefore, those of ordinary skill in the art may make various replacements, modifications, or changes, and combinations of example embodiments without departing from the scope of the present disclosure defined by the appended claims, and these replacements, modifications, or changes should be construed as being included in the scope of the present disclosure.

What is claimed is:

1. A semiconductor package, comprising:
a package substrate including a plurality of upper connection pads;
a semiconductor chip disposed on the package substrate and including a first surface facing the package substrate, the first surface including a first region and a second region; and
a plurality of connection bumps disposed below the first surface of the semiconductor chip and electrically connected to the plurality of upper connection pads,
wherein the plurality of connection bumps include a first group of connection bumps disposed within the first region of the first surface and a second group of connection bumps disposed within the second region of the first surface,
each of the first group of the connection bumps includes a first connection pillar and a first connection solder electrically connecting the first connection pillar to one of the plurality of upper connection pads,
each of the second group of the connection bumps includes a second connection pillar and a second connection solder electrically connecting the second connection pillar to one of the plurality of upper connection pads,
in a vertical direction, substantially perpendicular to the first surface, at least a portion of the second region has a greater separation distance from an upper surface of the package substrate than that of the first region, and
in at least one of the second group of connection bumps, an upper end of the second connection solder is disposed on a level lower than a level of an upper end of the first connection solder of each of the first group of the connection bumps.

2. The semiconductor package of claim 1, wherein in each of the first group of the connection bumps, the first connection solder includes a bonded portion in contact with the one of the plurality of upper connection pads below a lower surface of the first connection pillar, and a peripheral portion surrounding a side surface of the first connection pillar.

3. The semiconductor package of claim 2, wherein:
the peripheral portion of the first connection solder is in contact with the first surface of the semiconductor chip, and
in at least one of the second group of connection bumps, the second connection solder is spaced apart from the first surface of the semiconductor chip.

4. The semiconductor package of claim 2, wherein the peripheral portion of the first connection solder entirely covers the side surface of the first connection pillar.

5. The semiconductor package of claim 1, wherein 30% to 70% of the plurality of connection bumps are the first group of connection bumps, and the remainder thereof are the second group of connection bumps.

6. The semiconductor package of claim 1, wherein:
the first region is disposed on an inner side of the first surface, and the second region surrounds the first region, and
the second group of connection bumps are disposed to surround the first group of connection bumps.

7. The semiconductor package of claim 6, wherein in the vertical direction, an edge of the first surface includes a portion having a greater separation distance from the upper surface of the package substrate than the first region of the first surface.

8. The semiconductor package of claim 6, wherein the second group of connection bumps are disposed closer to an edge of the first surface than are the first group of connection bumps.

9. The semiconductor package of claim 1, wherein:
the second region is disposed on an inner side of the first surface, and the first region surrounds the second region, and
the first group of connection bumps are disposed to surround the second group of connection bumps.

10. The semiconductor package of claim 9, wherein in the vertical direction, an edge of the first surface includes a portion having a smaller separation distance from the upper surface of the package substrate than that of the second region of the first surface.

11. The semiconductor package of claim 1, wherein in the plurality of upper connection pads of the package substrate, upper surfaces of at least one of the upper connection pads connected to the first group of connection bumps are disposed closer to the first surface than are upper surfaces of each of the upper connection pads connected to the second group of connection bumps.

12. The semiconductor package of claim 1, further comprising:
an encapsulant covering the semiconductor chip and the plurality of connection bumps on the package substrate,
wherein in each of the first group of the connection bumps, the first connection pillar is spaced apart from the encapsulant, and
in at least one of the second group of connection bumps, the second connection pillar is in contact with the encapsulant.

13. A semiconductor package, comprising:
a package substrate including a first upper connection pad and a second upper connection pad;
a semiconductor chip disposed on the package substrate and electrically connected to the first upper connection pad and the second upper connection pad; and
connection bumps including a first connection bump connected to the first upper connection pad and a second connection bump connected to the second upper connection pad, which are disposed between the package substrate and the semiconductor chip,
wherein the first connection bump includes:
a first connection pillar on a lower surface of the semiconductor chip; and
a first connection solder covering a lower surface and a side surface of the first connection pillar and an upper surface of the first upper connection pad, and
the second connection bump includes:
a second connection pillar on the lower surface of the semiconductor chip; and
a second connection solder covering a lower surface of the second connection pillar and an upper surface of the second upper connection pad, and
wherein a first gap between the lower surface of the first connection pillar and the upper surface of the first upper connection pad is less than a second gap between the lower surface of the second connection pillar and the upper surface of the second upper connection pad.

14. The semiconductor package of claim 13, wherein a volume of the first connection solder is greater than a volume of the second connection solder.

15. The semiconductor package of claim 13, wherein a maximum planar area of the first connection bump is greater than a maximum planar area of the second connection bump.

16. The semiconductor package of claim 13, further comprising:
an encapsulant covering the semiconductor chip and the connection bumps on the package substrate,
wherein the encapsulant is in contact with the second connection pillar, and
the encapsulant is spaced apart from the first connection pillar.

17. The semiconductor package of claim 13, wherein a level difference between an upper end and a lower end of the first connection solder is greater than a level difference between an upper end and a lower end of the second connection solder.

18. A semiconductor package, comprising:
a package substrate body;
upper connection pads on an upper surface of the package substrate body;
a semiconductor chip on an upper surface of the package substrate body;
connection pillars on a lower surface of the semiconductor chip; and
connection solders disposed between the connection pillars and the upper connection pads and electrically connecting the upper connection pads and the connection pillars,
wherein the connection solders include:
a first connection solder in contact with a first upper connection pad, among the upper connection pads, and a first connection pillar, among the connection pillars; and
a second connection solder in contact with a second upper connection pad, among the upper connection pads, and a second connection pillar, among the connection pillars,
wherein the first connection solder surrounds at least a portion of a side surface of the first connection pillar, and
an area in which the first connection solder is in contact with the first connection pillar and the first upper connection pad is greater than an area in which the second connection solder is in contact with the second connection pillar and the second connection solder.

19. The semiconductor package of claim 18, further comprising:
an upper protective layer covering the upper surface of the package substrate body and including openings exposing upper surfaces of each of the upper connection pads,
wherein an area in which the first connection solder is contact with the upper protective layer is greater than an area in which the second connection solder is contact with the upper protective layer.

20. The semiconductor package of claim 18, wherein a maximum planar area of the first connection solder is greater than a maximum planar area of the second connection solder.
